(19) United States
(12) Patent Application Publication
(10) Pub. No.: US 2006/0084202 A1
(43) Pub. Date: Apr. 20, 2006

(54) Wafer Level Process for Manufacturing Leadframes and Device from the Same

(76) Inventors: Chien Liu, Kao-Hsiung City (TW); Meng-Jen Wang, Ping-Tung Hsien (TW); Sheng-Tai Tsai, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/163,134

(22) Filed: Oct. 6, 2005

(30) Foreign Application Priority Data
Oct. 19, 2004 (TW) 093131686

(51) Int. Cl. H01L 21/50; H01L 21/48

(52) U.S. Cl. 438/123; 438/124

(57) ABSTRACT

A wafer level process for fabricating leadframes is disclosed. A first mask is formed over an active surface of a wafer. The first mask includes a plurality of openings aligned with the wafer electrodes for forming a plurality of first leads on the wafer. A second mask is formed over the first mask with a plurality of grooves for forming a plurality of second leads. The second leads are connected to the corresponding first leads to form a leadframe. Next, the first mask and the second mask are removed to expose the active surface of the wafer and the first and second leads. Next, an encapsulant is applied on the wafer to seal the first leads and portions of the second leads.

### BACKGROUND OF THE INVENTION

1. Field of the Invention

The invention relates to a wafer level packaging process, and more particularly, to a wafer level packaging process for fabricating leadframes.

2. Description of the Prior Art

In the packaging of integrated circuits, leadframes are important devices commonly utilized as supporting and connecting medium for the integrated circuit (IC) chips. After the integrated circuits are fabricated, a wafer is diced to form a plurality of IC dies. Subsequently, the IC dies are attached to the die pad or leads of a leadframe utilizing silver paste, adhesion tape, or eutectic bonding layers during the packaging process.

According to recent packaging techniques, attempts have been made to integrate the fabrication of leadframe to a wafer thereby simplifying the packaging process, reducing the size of package, and increasing production volume. U.S. Pat. No. 6,407,333 discloses a method of fabricating a wafer level chip scale package, in which a leadframe larger than the conventional packaging scale is provided and attached to the active surface of a wafer. Next, a wire bonding process is performed to connect the solder pads of the die to the leadframe and an encapsulant is disposed on the active surface of the wafer to cover the leadframe. Subsequently, the wafer, together with the encapsulant, is diced to form a plurality of wafer level chip scale packages (WLCSP). However, the alignment of the leadframe with the wafer becomes a significant challenge when utilizing the conventional method. Moreover, the condition becomes much worse, when the die of the wafer includes a plurality of densely arranged die pads. The densely arranged die pads further increase the difficulty of accurately aligning the leads of the leadframe and electrically connecting the leadframe and the wafer.

### SUMMARY OF THE INVENTION

It is therefore an objective of the present invention to provide a wafer level process for fabricating leadframes. First, a plurality of masks are formed on a wafer, in which a plurality of leads can be fabricated individually on the wafer after corresponding openings or groves are formed in each mask. After the masks are removed, an encapsulant is disposed to seal the leads, in which the leads are able to connect to each other and accurately connect to the electrodes of the wafer. Consequently, the present invention is able to increase the density and number of the leads and reduce the effect of problems such as misalignment and faulty electrical connection between the leadframe and the wafer. Additionally, no extra electrical connection is required by the present invention and the number of fabrication steps can be reduced.

It is another aspect of the present invention to provide a wafer level process for fabricating leadframes, in which a first mask having a plurality of openings is formed on the active surface of a wafer to fabricate a plurality of first leads for connecting the electrodes of the wafer. Next, a second mask having a plurality of grooves is formed on the first mask to fabricate a plurality of second leads, in which the second leads are connected to the first leads to form an extending leadframe on the wafer.

It is another aspect of the present invention to provide a wafer level process for fabricating leadframes, in which an encapsulant is provided to seal the first leads and portions of the second leads. Preferably, the second leads also include a plurality of extended bonding surfaces exposed outside the encapsulant to provide electrical connection to the outside and ultimately produce a plurality of leadless wafer level chip scale packages.

It is another aspect of the present invention to provide a wafer level process for fabricating leadframes, in which the second mask includes a plurality of grooves and a plurality of opening regions to facilitate the formation of die pads and increase the heat dissipation and supporting ability of the die.

According to the present invention, a wafer level process for fabricating leadframes includes first providing a wafer, in which the wafer includes an active surface and a plurality of electrodes on the active surface. Next, a first mask is formed on the active surface of the wafer, in which the first mask includes a plurality of openings aligned with the electrodes. Next, a plurality of first leads is formed in the openings of the first mask, in which the first leads are connected to the corresponding electrodes. Next, a second mask is formed on the first mask, in which the second mask includes a plurality of grooves. Next, a plurality of second leads is formed in the grooves of the second mask, in which the second leads are connected to the first leads to form a leadframe. Next, the first mask and the second mask are removed to expose the active surface of the wafer, the first leads, and the second leads. Next, an encapsulation is formed on the active surface of the wafer to seal the first leads and portions of the second leads. Preferably, the second leads or leads formed toward the top also include a plurality of extended bonding surfaces exposed outside the encapsulant to serve as a conductive terminal to the outside and ultimately provide a plurality of leadless wafer level chip scale packages.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart diagram showing the wafer level process for fabricating leadframes according to the present invention.

FIG. 2 through FIG. 9 are perspective diagrams showing the means of fabricating leadframes from a wafer according to one embodiment of the present invention.

FIG. 10 is a perspective diagram showing a cross-section of a wafer level chip scale package according to the present invention.

FIG. 11 is a perspective diagram showing a top view of a wafer level chip scale package according to the present invention.

FIG. 12 through FIG. 17 are perspective diagrams showing the means of fabricating leadframes from a wafer according to another embodiment of the present invention.

### DETAILED DESCRIPTION

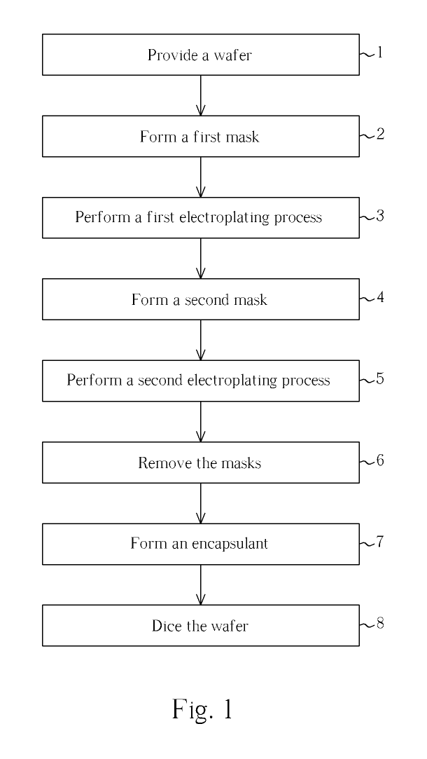

Please refer to FIG. 1. FIG. 1 is a flow chart diagram showing the wafer level process for fabricating leadframes according to the present invention. As shown in FIG. 1, the wafer level process includes the following nine steps: step 1, provide a wafer; step 2, form a first mask; step 3, perform a first electroplating process; step 4, form a second mask; step 5, perform a second electroplating process; step 6, remove the masks; step 7, form an encapsulant; and step 8, dice the wafer.

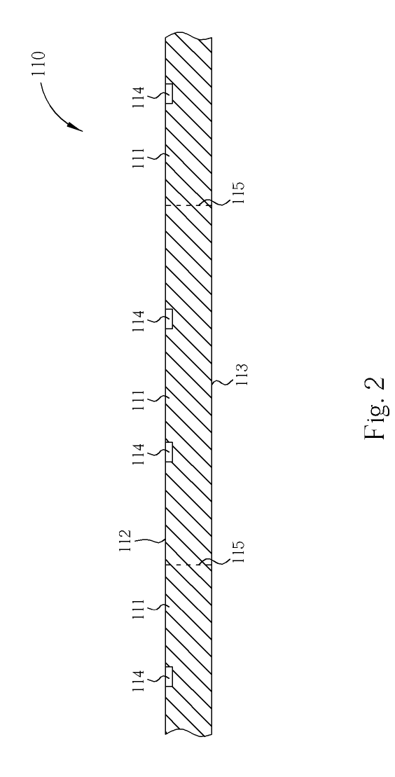

According to the first embodiment of the present invention, a wafer 110 is first provided, as shown in FIG. 2, in which the wafer 110 includes a plurality of IC dies 111. Preferably, a plurality of dicing lines 115 are defined between the IC dies 111 and the wafer 110 further includes an active surface 112 and a corresponding back surface 113, in which the active surface 112 includes a plurality of electrodes 114, such as solder pads or bumps for electrically connecting to the IC dies 111. According to the preferred embodiment of the present invention, the electrodes 114 are solder pads, in which the electrodes may include a pre-formed under bump metallurgy (UBM) structure (not shown).

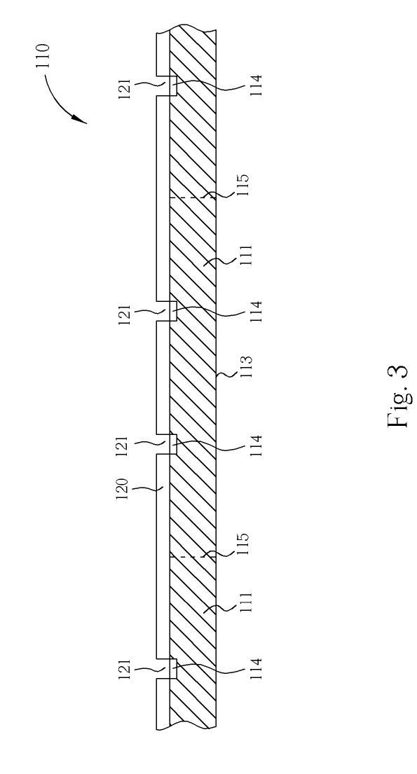

FIG. 3 corresponds to step 2 of forming a first mask. As shown in FIG. 3, a first mask 120 is formed on the active surface 112 of the wafer 110, in which the first mask 120 includes a plurality of openings 121 aligned with the electrodes 114. Preferably, the first mask 120 is composed of removable dielectric materials. According to the preferred embodiment of the present invention, the first mask 120 is composed of dry film, in which an exposure and development process can be performed to form the openings 121. Alternatively, the first mask 120 can also be composed of photoresist of a desired thickness. Preferably, the first mask 120 is composed of a conductive dry film, such that the conductive surface of the film is attached to the wafer 110 to facilitate the electroplating process performed thereafter for forming a plurality of first leads 131.

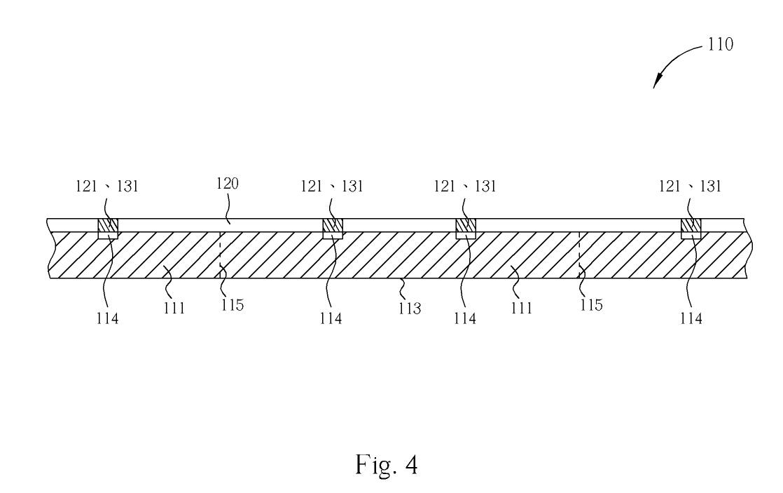

FIG. 4 corresponds to step 3 of performing a first electroplating process. As shown in FIG. 4, an electroplating or electroless plating process is performed to form a plurality of first leads 141 in the openings 121 of the first mask 120, in which the first leads 131 are connected to the corresponding electrodes 114. According to the preferred embodiment of the present invention, the openings 121 of the first leads are vertical openings and the first leads 131 formed within the openings are vertical column-shaped. Preferably, the first leads 131 are round column-shaped to facilitate the formation of the encapsulant 160. Additionally, the first leads are composed of copper.

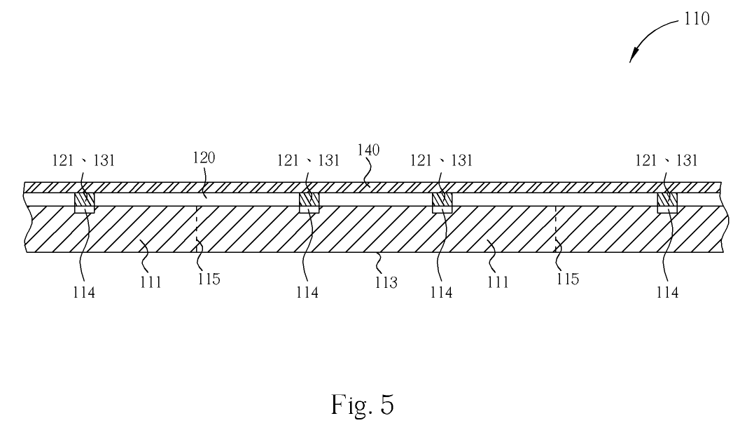

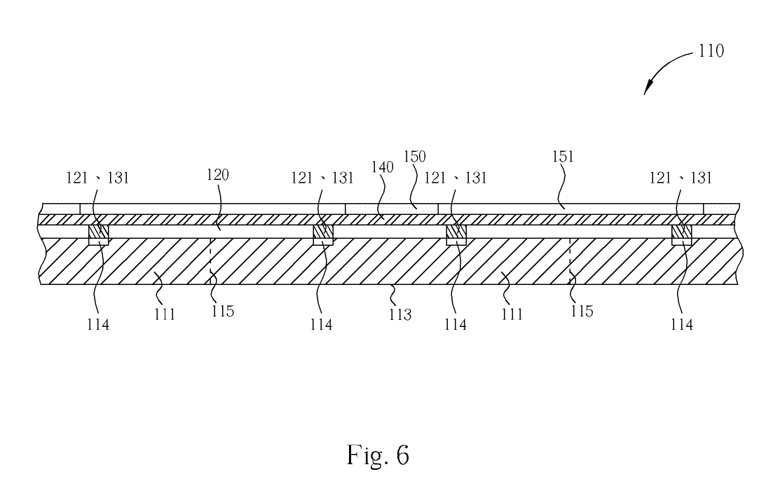

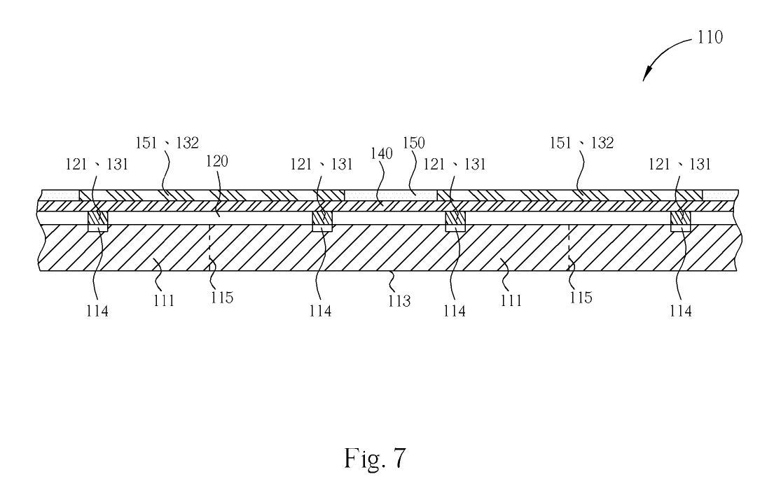

Subsequently, an electroplating or electroless plating process is performed to form a plurality of second leads 132 to connect to the first leads and form a leadframe, as shown in FIG. 7. Nevertheless, the formation of the second leads 132 may vary depending on various fabrication processes. FIG. 5 corresponds to step 4 of forming a second mask. As shown in FIG. 5, when the second leads 132 are formed utilizing the electroplating process, a seed layer 140 is first formed on the first mask 120 by utilizing a sputtering or vapor deposition process. As shown in FIG. 6, a second mask 150, such as a dielectric dry film is formed on the first mask 120, in which an exposure or development process is performed to form a plurality of grooves 151 on the second mask 150 to facilitate the electroplating process performed afterwards for forming a plurality of second leads 132. Alternatively, the second mask 150 can be composed of conductive dry film having a conductive surface, in which the conductive surface is attached to the first mask 120. By utilizing this method, the electroplating process can be performed to form the second leads 132 without forming the seed layer 140. Preferably, the second mask 150 is composed of dry films, such as the same photoresist material used in the first mask 120, in which the first mask 120 and the second mask 150 can be removed simultaneously by the same photoresist remover.

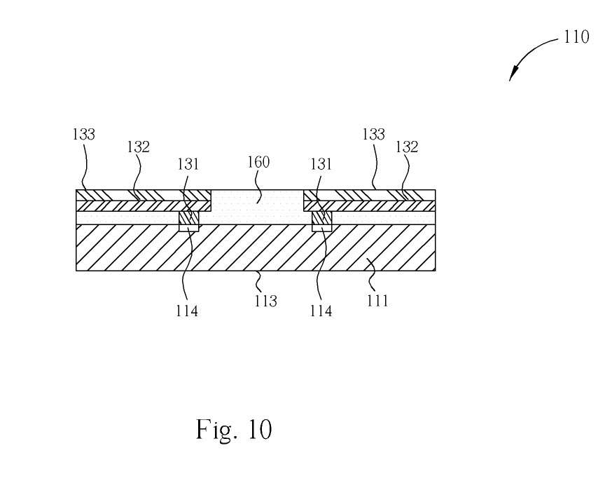

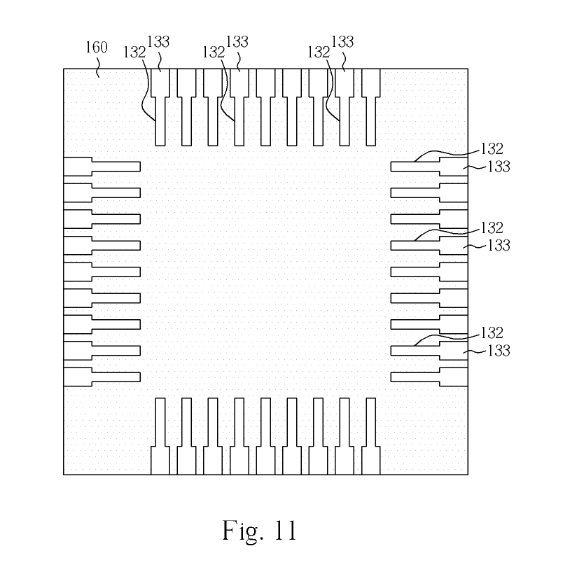

FIG. 7 corresponds to step 5 of performing a second electroplating process. As shown in FIG. 7, the second leads 132 are formed in the grooves 151 of the second mask 150, such that the second leads 132 are connected to the first leads to form a leadframe (not shown) according to a predetermined and extended direction. Preferably, the second leads 132 are comprised of copper. According to the preferred embodiment of the present invention, the extended direction of the second leads 132 is fanning out in the horizontal direction and vertical to the first leads 131. Additionally, the leadframe is composed of the first leads 131 and the second leads 132, in which the second leads 132 may include a plurality of extended bonding surfaces 133 for serving as a conductive terminal to the outside, as shown in FIG. 10 and FIG. 11. Preferably, the exposed area of the second leads 132 function as the extended bonding surfaces 133, in which the area of the extended bonding surfaces 133 is greater than the connective surface of the first leads 131 and the corresponding second leads 132. Additionally, if more leads were to be fabricated, step 4 and step 5 previously described can be performed repeatedly to form a plurality of third leads (not shown) or other additional leads for connecting to the second leads 132.

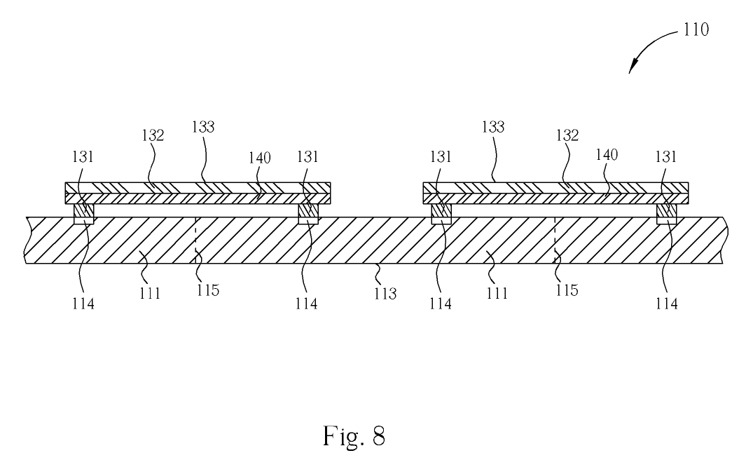

FIG. 8 corresponds to step 6 of removing the mask. As shown in FIG. 8, the first mask 120 and the second mask 150 are removed to expose the active surface 112 of the wafer 110, the first leads 131, and the second leads 132. According to the preferred embodiment of the present invention, the seed layer 140 can be removed utilizing the photoresist remover in the same step or removed utilizing another etching process. After removing the mask, the second leads 132 are suspended above the active surface 112 of the wafer 110.

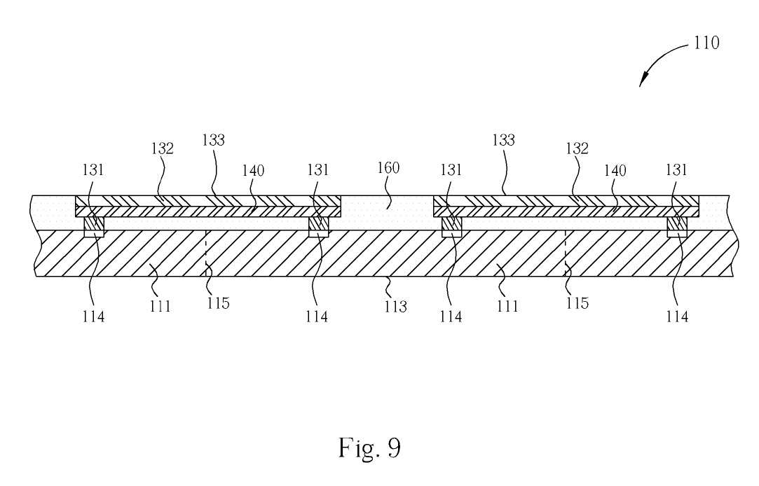

FIG. 9 corresponds to step 7 of forming an encapsulant. As shown in FIG. 9, a molding, printing, spin coating, or dispensing process is performed to form an encapsulant 160 on the active surface 112 of the wafer 110 for sealing the first leads 131 and portions of the second leads 132. Preferably, a planarizing polishing process can be performed to produce an encapsulant 160 with a highly smooth outer surface. According to the preferred embodiment of the present invention, the extended bonding surface 133 of the second leads 132 are exposed outside the encapsulant 160 to serve as the conductive terminal to the outside. After the encapsulant 160 is solidified, the position of the first leads 131 and the second leads 132 can also be fixed accordingly.

Additionally, step 8 of the present invention also includes a process of dicing the wafer, in which the step involves dicing the wafer 110 and the encapsulant 160 along the dicing lines 115 to form a plurality of leadless wafer level chip scale packages, as shown in FIG. 10 and FIG. 11.

According to the wafer level process described above, the first leads 131 and the second leads 132 are gradually formed on the wafer 110, in which no wire bonding or flip chip processes are required to establish an electrical connection. As a result, the first leads 131 of the leadframe are able to accurately connect to the electrodes 114 of the wafer 110. By fabricating micro-leadframes on the wafer, the present invention is able to increase the density and number of leads and reduce the effect of problems such as misalignment and faulty electrical connection between the leadframe and the wafer.

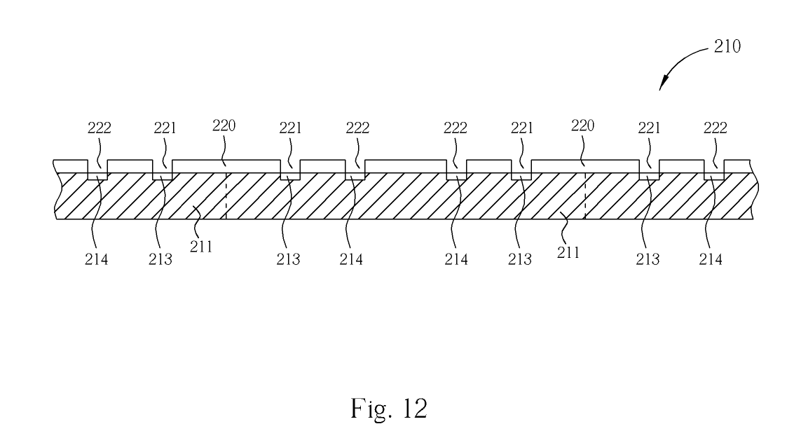

Additionally, the wafer level process for fabricating leadframes according to the present invention is not limited to the finished state of the leadframe. According to the second embodiment of the present invention, a wafer 210 including a plurality of integrated circuits 211 is first provided, in which the wafer 210 includes an active surface 212 and a plurality of electrodes 213 disposed on the active surface 212, as shown in FIG. 12. Preferably, the wafer 210 also includes a plurality of dummy pads 214.

FIG. 12 corresponds to step 2 of forming a first mask. As shown in FIG. 12, a first mask 220 is formed on the active surface 212 of the wafer 210. By utilizing exposure and development processes, the first mask 220 is patterned to form a plurality of openings 221, in which the openings 221 are aligned corresponding to the electrodes 213 for forming a plurality of first leads 231. According to the present embodiment, the first mask 220 also includes a plurality of dummy holes 222 aligning to the dummy pads 214 of the wafer 210.

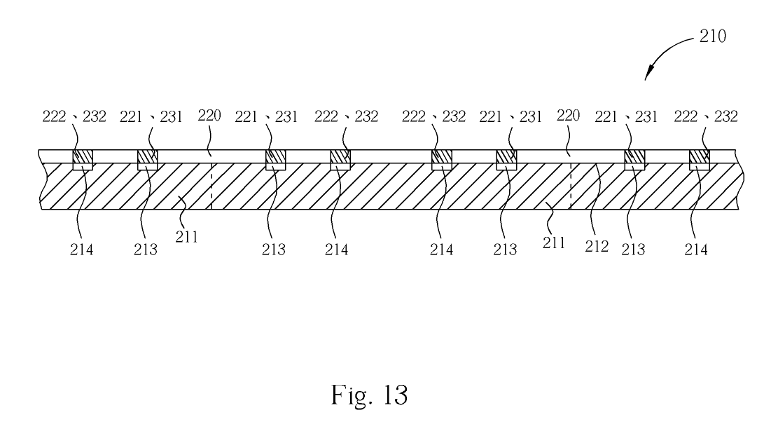

FIG. 13 corresponds to step 3 of performing a first electroplating process. As shown in FIG. 13, an electroplating process is performed to form a plurality of first leads 231 in the openings 221 of the first mask 220, in which the first leads 231 are connected to the corresponding electrodes 213. According to the present embodiment, a plurality of tie bars 232 are formed in the dummy holes 222 of the first mask 220.

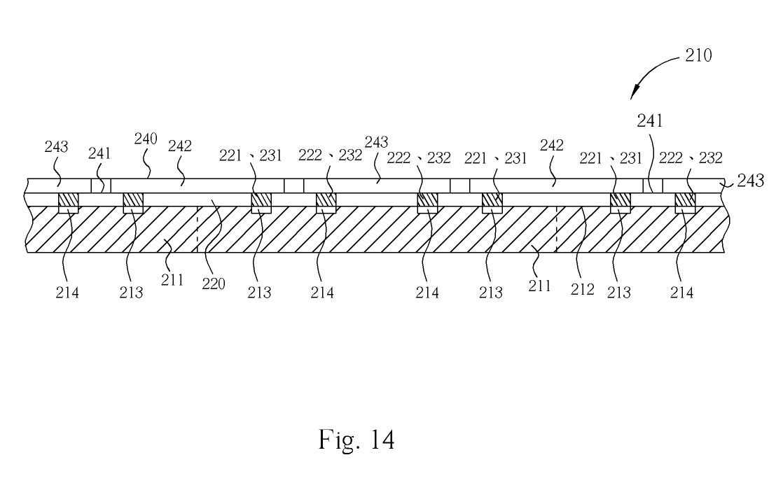

FIG. 14 corresponds to step 4 of forming a second mask. As shown in FIG. 14, a second mask 240 is formed on the first mask 220. According to the present embodiment, the second mask 240 includes a conductive surface 241 attached to the first mask 220. After the second mask 240 is patterned, a plurality of grooves 242 and opening regions 243 is formed in the second mask 240 to facilitate the formation of a plurality of second leads 233 and die pads 234.

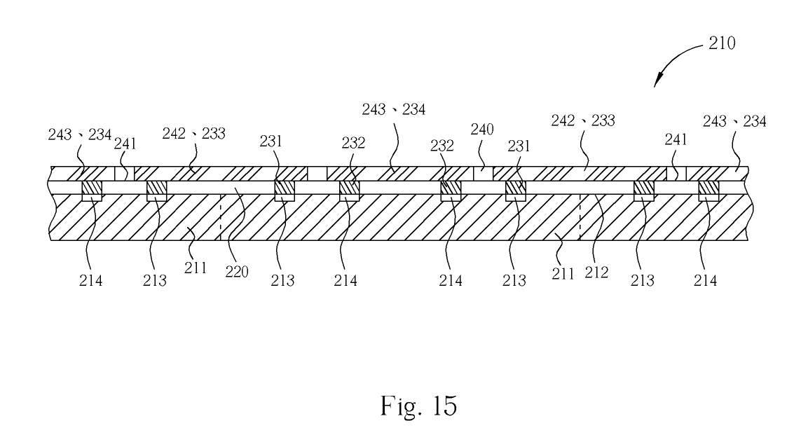

FIG. 15 corresponds to step 5 of performing a second electroplating process. As shown in FIG. 15, the second leads 233 are formed in the groves 242 of the second mask 240 and the die pads 234 are formed in the opening regions 243 of the second mask 240. Preferably, the second leads 233 are extended according to a predetermined direction and connected to the supporting first leads 231, and the die pads 234 are connected to the tie bars 232, in which the die pads 234 are supported by the tie bars 232. Consequently, the present embodiment includes the ability to fabricate a leadframe (not shown) including the first leads 231, the second leads 233, and the die pads 234 on the wafer 210.

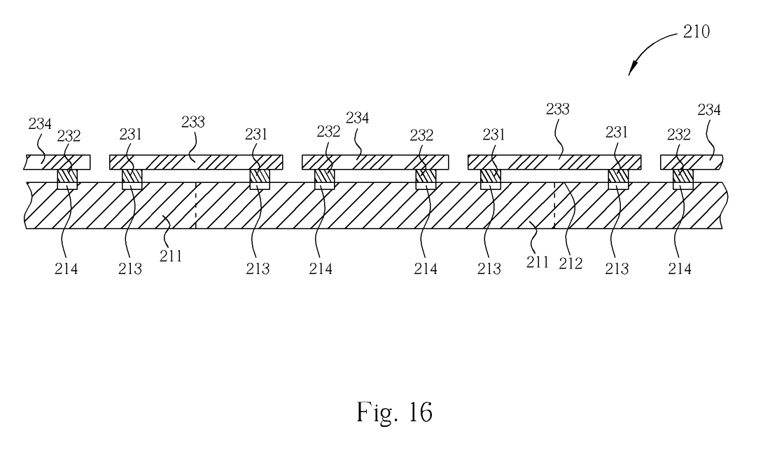

FIG. 16 corresponds to step 6 of removing the mask. As shown in FIG. 16, the first mask 220 and the second mask 240 are removed to expose the active surface 212 of the wafer 210, the first leads 231, the second leads 233, and the die pads 234.

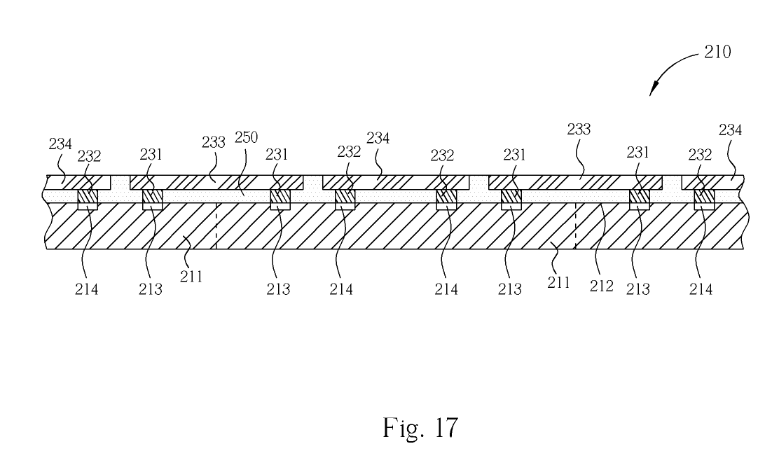

FIG. 17 corresponds to step 7 of forming an encapsulant. As shown in FIG. 17, a molding process or other process such as those discussed previously can be utilized to form an encapsulant 250 on the active surface 212 of the wafer 210 for sealing the first leads 231, the tie bars 232, part of the second leads 233, and part of the die pads 234. Preferably, the extended bonding surface 235 of the second leads and the upper surface of the die pads 234 are exposed outside the encapsulant 250 to facilitate heat dissipation, grounding, and electrical conduction to the outside. By fabricating micro-leadframes on the wafer, the present invention is able to effectively increase the density and number of the leads.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer level process for fabricating leadframes, wherein the leadframe comprises a plurality of first leads and a plurality of second leads, the wafer level process comprising:
providing a wafer, wherein the wafer comprises an active surface and a plurality of electrodes on the active surface;
forming a first mask on the active surface of the wafer, wherein the first mask comprises a plurality of openings aligned with the electrodes;
forming the plurality of first leads in the openings of the first mask, wherein the first leads are connected to the corresponding electrodes;
forming a second mask on the first mask, wherein the second mask comprises a plurality of grooves;
forming the plurality of second leads in the grooves of the second mask, wherein the second leads are connected to the first leads;
removing the first mask and the second mask for exposing the active surface of the wafer, the first leads, and the second leads; and
forming an encapsulation on the active surface of the wafer for sealing the first leads and portions of the second leads.

2. The wafer level process for fabricating leadframes of claim 1, wherein the first leads are formed by an electroplating or an electroless plating processes.

3. The wafer level process for fabricating leadframes of claim 2, wherein the second leads are formed by the electroplating or the electroless plating processes.

4. The wafer level process for fabricating leadframes of claim 3 further comprising:
forming a seed layer on the upper surface of the first mask before the formation of the second mask for facilitating the formation of the second leads utilizing the electroplating process.

5. The wafer level process for fabricating leadframes of claim 1, wherein the first mask comprises dry film.

6. The wafer level process for fabricating leadframes of claim 5, wherein the second mask comprises dry film or a same material as the first mask.

7. The wafer level process for fabricating leadframes of claim 1, wherein the second mask further comprises an opening for forming a die pad utilizing an electroplating process.

8. The wafer level process for fabricating leadframes of claim 7 further comprising forming the die pad in the opening of the second mask while forming the second leads.

9. The wafer level process for fabricating leadframes of claim 8, wherein the first mask further comprises a plurality of dummy holes to form a plurality of tie bars utilizing the electroplating process for supporting the die pad.

10. The wafer level process for fabricating leadframes of claim 9 further comprising forming the tie bars in the dummy holes while forming the first leads.

11. The wafer level process for fabricating leadframes of claim 1 further comprising dicing the wafer and the encapsulant for forming a plurality of wafer level chip scale packages.

12. The wafer level process for fabricating leadframes of claim 1, wherein the first leads are vertical column shaped.

13. The wafer level process for fabricating leadframes of claim 12, wherein the extension direction of the second leads are horizontal and vertical to the first leads.

14. The wafer level process for fabricating leadframes of claim 1, wherein the second leads comprise a plurality of extended bonding surfaces exposed outside the encapsulant.

15. The wafer level process for fabricating leadframes of claim 1 further comprising forming a plurality of third leads on the second mask for connecting to the second leads.
